(19) United States
(12) Patent Application Publication
(10) Pub. No.: US 2026/0180616 A1
(43) Pub. Date: Jun. 25, 2026

(54) ISOLATION-FILTERING UNIT

(71) Applicant: Telefonaktiebolaget LM Ericsson (publ), Stockholm (SE)

(72) Inventors: Junming Li, Beijing (CN); Yanju Han, Beijing (CN); Juandi Song, Beijing (CN)

(21) Appl. No.: 18/730,440

(22) PCT Filed: Sep. 22, 2022
(86) PCT No.: PCT/CN2022/120510

§ 371 Date: Jul. 19, 2024

(30) Foreign Application Priority Data
Jan. 21, 2022 (WO) PCT/CN2022/073106

(51) Int. Cl. H04B 1/525; H01P 1/213; H03H 9/72

(52) U.S. Cl. CPC H04B 1/525; H01P 1/213; H03H 9/725

(57) ABSTRACT

Disclosed is an isolation-filtering unit configured for performing both an isolation function and a filtering function. The isolation-filtering unit includes an isolation function portion and a filtering function portion, wherein the isolation function portion is integrated with the filtering function portion as a whole, and wherein the isolation function portion operates as a circulator or an isolator.

### CROSS-REFERENCE TO RELATED APPLICATIONS

This application claims priority of PCT application PCT/CN2022/073106 which was filed on 21 Jan. 2022 and which are incorporated herein in its entirety by reference.

### TECHNICAL FIELD

The present disclosure generally relates to the field of telecommunications technology, and in particular, to an isolation-filtering unit.

### BACKGROUND

This section is intended to provide background or context for specific embodiments of the present disclosure described in claims. The description herein may include concepts which are intended to be claimed and may be concepts that have not been conceived, implemented or described previously. Therefore, the content described in this section should not be considered as the related art to the description and claims of the present disclosure although it is included in this section, unless otherwise stated.

In BS (referring to Base Station herein) solution, circulator/isolator unit is functioned as isolation between input and output in TX path (referring to Transmit path herein) and RX path (referring to Receive path herein). Filter unit is used to attenuate the out-of-band unwanted emission or blocking signal. In traditional BS solution, circulator/isolator unit and filter unit are separated as two independent units, and normally circulator/isolator unit is mounted on printed circuit board, while filter unit is assembled within EMC (referring to Electro Magnetic Compatibility herein) cover or mounted on printed circuit board but separated from circulator/isolator unit.

For BS solution design, the IL (referring to Insertion Loss herein) of circulator/isolator unit and filter unit is a key parameter. In TX path, it decides the power level of PA (referring to power amplifier herein). In RX path, it decides RX sensitivity level. It also impacts the radio product's power consumption and size/weight. Minimizing the IL from circulator/isolator unit's input to filter unit's output is always the target to optimize BS solution. The IL of the filter unit is tightly dominated by out-of-band attenuation requirements of this filter unit. And the mismatch between circulator/isolator unit and filter unit also makes the IL worse. For traditional solution where filter unit and circulator/isolator unit are separated, the IL is degraded by the batch margin and mismatch between circulator/isolator unit and filter unit. And it is hard to foresee the all attenuation level of circulator/isolator unit. When setting out-of-band requirement of filter unit, the circulator/isolator unit's attenuation contribution at some frequency range can't be used. It will result stringent out-of-band requirement, correspondingly the IL is hard to improve.

In addition, separated filter unit and circulator/isolator unit also encounter size drawback. In addition, the cost of separated filter unit and circulator/isolator unit are key part of the cost of a Radio such as AAS (referring to Advanced Base Station) radio, and macro radio and micro radio, etc.

### SUMMARY

In view of the above, embodiments of the present disclosure is to provide an isolation-filtering unit in order to overcome at least one aspect of the above-mentioned and other disadvantages and defects in the related art.

According to one aspect of the present disclosure, there is provided an isolation-filtering unit configured for performing both an isolation function and a filtering function. The isolation-filtering unit includes an isolation function portion and a filtering function portion, wherein the isolation function portion is integrated with the filtering function portion as a whole, and wherein the isolation function portion operates as a circulator or an isolator.

In some embodiments of the present disclosure, the isolation function portion is non-conductively coupled to the filtering function portion, or the isolation function portion is conductively connected to the filtering function portion.

In some embodiments of the present disclosure, the isolation-filtering unit has at least one isolation function input port and at least one filtering function input-output port.

In some embodiments of the present disclosure, the isolation-filtering unit has first, second and third ports, wherein the first and second ports are configured for transmitting a signal from the first port to the second port and isolating a signal transmitted from the second port to the first port while achieving a filtering function; wherein the second and third ports are configured for transmitting a signal from the second port to the third port and isolating a signal transmitted from the third port to the second port while achieving a filtering function; wherein the first and third ports are configured for isolating a signal transmitted from the first port to the third port; and wherein the third port is selectively configured for being terminated by a load.

In some embodiments of the present disclosure, the isolation-filtering unit comprises a chassis for both the isolation function portion and the filtering function portion.

In some embodiments of the present disclosure, the filtering function portion comprises the chassis and a plurality of resonators provided within the chassis, the isolation function portion comprises the chassis and a center conductor provided within the chassis, and the resonators are connected to the center conductor by a connecting conductor.

In some embodiments of the present disclosure, the connecting conductor is extended from the center conductor of the isolation function portion and is connected to the resonators of the filtering function portion.

In some embodiments of the present disclosure, the connecting conductor is connected to the resonators by soldering or by pressing or by rivet connection.

In some embodiments of the present disclosure, the center conductor is inductively coupled to the resonators; or the center conductor is capacitively coupled to the resonators.

In some embodiments of the present disclosure, the central conductor of the isolation function portion and the resonators of the filtering function portion are integrally formed as one sheetmetal; and the connecting conductor is an integral part of the one sheetmetal.

In some embodiments of the present disclosure, the chassis, the resonators and the connecting conductor each is made of a metal material, or of a plastic material with a metalized surface.

In some embodiments of the present disclosure, the isolation-filtering unit further comprises: a cover provided over the chassis to enclose the resonators, the connecting conductor and the isolation function portion.

In some embodiments of the present disclosure, the cover is made of a metal material, or of a plastic material with a metalized surface.

In some embodiments of the present disclosure, the filtering function portion comprises a ceramic body, and the isolation function portion comprises a ferrite disc provided on the ceramic body and a magnetic disc provided on the ferrite disc; wherein the ceramic body also serves as a carrier for the isolation function portion.

In some embodiments of the present disclosure, the ceramic body has through holes therein; the ferrite disc comprises conductive traces separated from each other and extended from an upper surface to a bottom surface of the ferrite disc; and the conductive traces are respectively conductively connected to the through holes at the bottom surface of the ferrite disc.

In some embodiments of the present disclosure, each conductive trace is extended from the upper surface to the bottom surface of the ferrite disc via a side surface of the ferrite disc; or each conductive trace is extended from the upper surface to the bottom surface of the ferrite disc via a conductive post provided to the side surface of the ferrite disc; or each conductive trace is extended from the upper surface to the bottom surface of the ferrite disc via a metalized through hole formed from the upper surface to the lower surface of the ferrite disc.

With the isolation-filtering unit provided in the present disclosure, the isolation function portion and the filtering function portion are integrated as a whole and the isolation function portion operates as a circulator or an isolator, and the IL from the isolation function portion and the filtering function portion is reduced since mismatch between the isolation function portion and the filtering function portion is reduced, the trace length between the isolation function portion and the filtering function portion is reduced and the out-of-band attenuation requirement on the isolation-filtering unit is relaxed. With the isolation-filtering unit provided in the present disclosure, the out-of-band attenuation requirement on the isolation-filtering unit is relaxed due to removing extra margin and mismatch as well as utilizing the out-of-band rejection brought by the isolation function portion. In addition, with the isolation-filtering unit provided in the present disclosure, total BOM (referring to Bill of Materials) cost is reduced since some manufacture processes are saved compared with the circulator/isolator unit and the filter unit in traditional separated design. In addition, weight and size of a Radio including the isolation-filtering unit is reduced since the power amplifier's output power are significant reduced which is benefit from the improved IL of the isolation-filtering unit and smaller size of the isolation-filtering unit.

### BRIEF DESCRIPTION OF THE DRAWINGS

Accompanying drawings of embodiments of the present disclosure will be briefly described below in order to more clearly describe technical solutions of the embodiments of the present disclosure. It should be understood that the accompanying drawings described below only refer to some embodiments of the present disclosure, rather than limiting the present disclosure, in which:

FIG. 1 illustrates a Radio link according to an example solution, showing positions of circulator/isolator unit and filter unit in the Radio link;

FIG. 2 shows a perspective view of an isolation-filtering unit according to a first exemplary embodiment of the present disclosure, where a cover of the isolation-filtering unit is removed for illustrating components and/or structure in a chassis;

FIG. 3 shows an exploded view of the isolation-filtering unit according to the first exemplary embodiment of the present disclosure;

FIG. 4 is an exploded view showing an alternative of the isolation-filtering unit according to the first exemplary embodiment of the present disclosure;

FIG. 5 is a perspective view of the sheet metal shown in FIG. 4;

FIG. 6 shows a perspective view of an isolation-filtering unit according to a second exemplary embodiment of the present disclosure from a top view;

FIG. 7 shows a perspective view of the isolation-filtering unit according to the second exemplary embodiment of the present disclosure from a bottom view;

FIGS. 8A and 8B are respectively top and bottom views of a ferrite disc and a magnetic disc of the isolation-filtering unit according to the second exemplary embodiment of the present disclosure;

FIG. 9 shows a partial view of a ceramic body of the isolation-filtering unit according to the second exemplary embodiment of the present disclosure from a top view, illustrating one signal transmission path in the ceramic body; and

FIGS. 10A and 10B illustrate RF performance of the isolation-filtering unit according to first and second exemplary embodiments of the present disclosure, respectively.

### DETAILED DESCRIPTION

In order to more clearly illustrate objectives, technical solutions, and advantages of the present disclosure, embodiments of the present disclosure will be described in detail below with reference to the accompanying drawings. It should be understood that the following description of the embodiments is intended to explain and illustrate general idea of the present disclosure, and should not be construed as a limitation to the present disclosure. In the description and the accompanying drawings, same or similar reference signs refer to same or similar elements or components. For sake of clarity, the drawings are not necessarily drawn to scale, and some well-known components and structures may be omitted from the drawings.

The technical or scientific terms used herein shall have common meanings understood by those ordinary skilled in the art, unless otherwise stated. The words “first”, “second” and similar words used herein are merely intended to distinguish different elements or components, rather than indicating any order, quantity or importance. The word “a” or “an” does not exclude a plurality. The word “comprise”, “include” or other similar words means that an element or item appearing before the word covers an element or item listed and their equivalents after the word, but does not exclude other elements or items. The word “connect”, “connection” or other similar words are not limited to physical or mechanical connections, and may include direct or indirect electrical connection. The word “up”, “down”, “left”, “right”, “top” or “bottom” is merely used to indicate the relative position relationship. When an absolute position of a described object is changed, its relative position relationship may also be accordingly changed. When an element such as a layer, a film, a region, or a substrate is described as “on” or “under” another element, the element may be “directly” “on” or “under” the another element, or there may be an intermediate element.

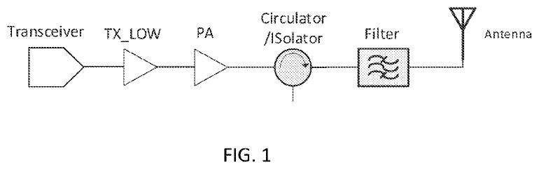

FIG. 1 illustrates a Radio link according to an example solution. As shown in FIG. 1, the circulator/isolator unit and the filter unit are neighbor in the Radio link. In traditional design, circulator/isolator unit and filter unit are two separated units.

The present disclosure provides a solution to integrate the circulator/isolator unit and the filter unit in traditional separated design into one unit.

According to the present disclosure, there is provided an isolation-filtering unit configured for performing both an isolation function and a filtering function. The isolation-filtering unit comprises an isolation function portion and a filtering function portion. The isolation function portion is integrated with the filtering function portion as a whole. The isolation function portion operates as a circulator or an isolator.

In the present disclosure, the isolation-filtering unit comprises the isolation function portion and the filtering function portion, and the isolation function portion is integrated with the filtering function portion as a whole. Herein, the phase “be integrated with” indicates the isolation function portion and the filtering function portion have at least one common structure/component or share at least one structure/component so that the two portions are technologically incorporated or combined into one unit or form an indivisible cooperating design, other than simply assembling the two portions together or locating one portion into the other portion. In other words, the isolation-filtering unit is a united unit which is capable of performing both an isolation function and a filtering function.

According to the present disclosure, the isolation function portion enables the isolation-filtering unit to function as an isolator or a circulator and the filtering function portion enables the isolation-filtering unit to function as a filter. The isolation-filtering unit according to the present disclosure can be also named as “circulation and filtering unit” or “circulator and filter unit” (which is also shortened as “CFU” herein) or “isolator and filter unit” or “circulator/isolator and filter unit”, or the like.

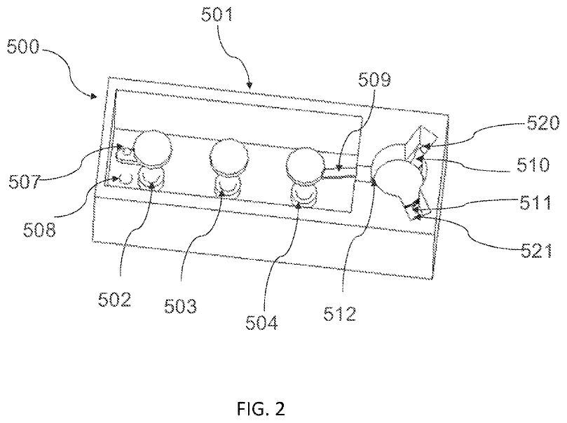

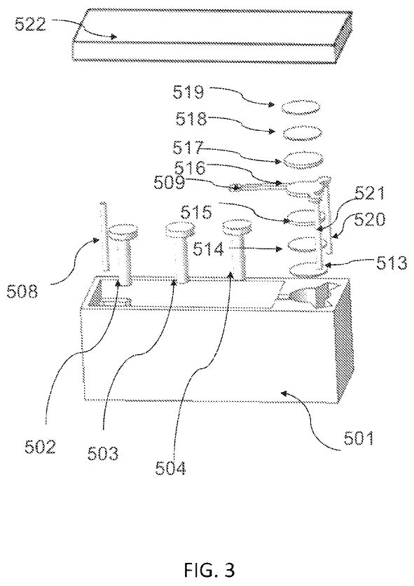

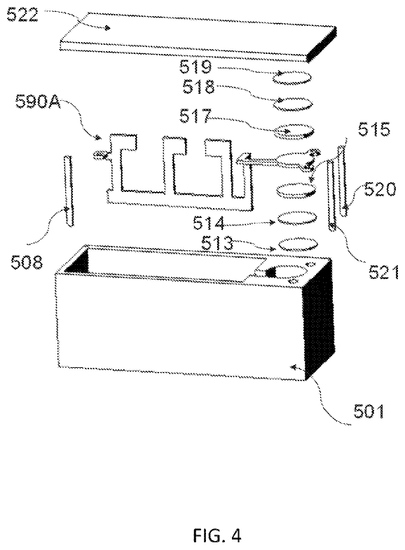

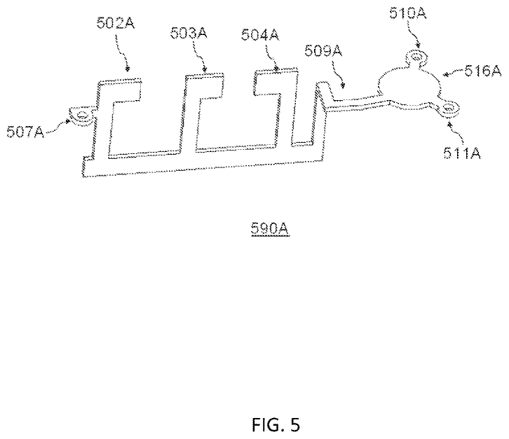

According to the present disclosure, in the isolation-filtering unit, the isolation function portion is communicatively coupled to the filtering function portion. That is to say, the isolation function portion can be conductively connected to the filtering function portion, or the isolation function portion can be non-conductively (i.e., capacitively or inductively) coupled to the filtering function portion. In an exemplary embodiment, the isolation function portion is conductively (inductively) connected to the filtering function portion by a connecting conductor (which will be described in detail hereinafter with reference to FIG. 2, FIG. 3, FIG. 4 and FIG. 5). In some other embodiments, a RF signal coupling between the center conductor and the resonators is used. For one example, the center conductor is capacitively coupled to the resonators, and signal coupling between the center conductor and the resonators is achieved by two adjacent surfaces of the center conductor and the resonators. For another example, the center conductor is inductively coupled to the resonators, and signal coupling between the center conductor and the resonators is achieved by a loop structure with grounding.

According to the present disclosure, the isolation-filtering unit has at least one isolation function input port and at least one filtering function input-output port. In the exemplary embodiments of the present disclosure, the isolation-filtering unit has first, second and third ports, wherein the first and second ports are configured for transmitting a signal from the first port to the second port and isolating a signal transmitted from the second port to the first port while achieving a filtering function; wherein the second and third ports are configured for transmitting a signal from the second port to the third port and isolating a signal transmitted from the third port to the second port while achieving a filtering function; wherein the first and third ports are configured for isolating a signal transmitted from the first port to the third port; and wherein the third port is selectively configured for being terminated by a load.

According to the present disclosure, from another view, the isolation-filtering unit has three ports, the isolation function portion uses two ports of the three ports and the filtering function portion uses the rest port of the three ports when the isolation function portion operates as the circulator; and the isolation function portion uses one port of the three ports and the filtering function portion uses the rest ports of the three ports when the isolation function portion operates as the isolator. The isolation-filtering unit at least has three ports: an input port, an output port and a filtering function in-out port. Both isolation function and filtering function are achieved from the input port to the filtering function in-out port. Both isolation function and filtering function are achieved from the filtering function in-out port to the output port. In a TDD (referring to Time division Duplex herein) scenario, the isolation function portion of the isolation-filtering unit operates as the circulator and uses the input port and the output port of the isolation-filtering unit, and the filtering function portion uses the filtering function in-out port of the isolation-filtering unit. In a FDD (referring to Frequency division Duplex herein) scenario, the isolation function portion of the isolation-filtering unit operates as the isolator and uses the input port of the isolation-filtering unit, the remaining two ports of the isolation-filtering unit acts as the filtering function in-out ports of the filtering function portion, and the output port of the isolation-filtering unit is terminated by a load, such as an impedance normally of 50 Ω. In addition, in a TX only scenario, the isolation function portion of the isolation-filtering unit operates as the isolator and uses the input port of the isolation-filtering unit, the filtering function portion uses the filtering function in-out port of the isolation-filtering unit, and the output port of the isolation-filtering unit is terminated by a load, such as an impedance normally of 50 Ω. Anyway, as a result, requirement from the isolation function portion's input to the filtering function portion's output can be set as a whole, i.e., co-design of the two portions.

According to the present disclosure, the isolation-filtering unit is very flexible in filter technology and circulator/isolator technology. The filtering function portion can use any technology such as metal cavity filter, plastic metallization cavity filter, sheet metal filter and CWG (referring to Ceramic Waveguide herein) filter, etc. And the isolation function portion can use any technology such as SMD (referring to Surface Mounted Device herein) circulator/isolator, thick film microstrip circulator/isolator, etc.

FIG. 2 and FIG. 3 show an isolation-filtering unit according to a first exemplary embodiment of the present disclosure. In this exemplary embodiment, referring to FIG. 2 and FIG. 3, the isolation-filtering unit 500 comprises a chassis 501 for both the filtering function portion and the isolation function portion. That is, the filtering function portion in this exemplary embodiment operates as a band pass cavity filter. Specifically, the filtering function portion comprises the chassis 501, and a plurality of resonators 502, 503, 504 provided within the chassis 501, and a cover 522 provided over the chassis 501 to enclose the plurality of resonators 502, 503, 504. The resonators 502, 503, 504 (acting as inner conductors), and the chassis 501 and the cover 522 (both acting as outer conductor) together achieve the filtering function. The isolation function portion, as shown in FIG. 2 and FIG. 3, mainly includes a center conductor 516, ferrite discs 517, 515 and magnets 519, 518, 514, 513, all of which are provided within the chassis 501. In other words, in this exemplary embodiment, the chassis 501 provides both out conductor of the filtering function portion and the isolation function portion at the same time. In addition, the chassis 501 also provides a mechanical chassis for EMC shielding, grounding, assembling, and other functions. It should be noted that, the chassis 501 may have a plurality of cavities formed therein, for example, the resonators 502, 503, 504 of the filtering function portion are located within one cavity while the center conductor 516, ferrite discs 517, 515 and magnets 519, 518, 514, 513 of the isolation function portion are located within another cavity.

According to the first exemplary embodiment of the present disclosure, as shown in FIG. 2 and FIG. 3, in the isolation-filtering unit 500, the plurality of resonators 502, 503, 504 are connected to the center conductor 516 by a connecting conductor 509. In this exemplary embodiment shown in FIG. 2 and FIG. 3, the plurality of resonators 502, 503, 504 are connected in series with each other, the connecting conductor 509 is extended from the center conductor 516 of the isolation function portion and is connected to one resonator 504 of the filtering function portion. For example, the connecting conductor 509 is connected to the resonator 504 by soldering or by pressing or by rivet connection, or by other suitable process. Moreover, the isolation-filtering unit 500 further comprises one port 508 connected with another resonator 502 via an input/output conductor 507, and two ports 520, 521 respectively connected with the center conductor 516 via input/output conductors 510, 511. Here, the three ports 508, 520, 521 will respectively act as the input port, the output port and the filtering function in-out port of the isolation-filtering unit 500, depending on different application scenarios as mentioned above. Accordingly, the isolation-filtering unit 500 achieves the filtering function by the input/output conductor 507, the resonators 502, 503, 504 (acting as inner conductors), and the chassis 501 and the cover 522 (both acting as outer conductor), at the same time, the isolation-filtering unit 500 achieves the isolation function by the center conductor 516, the ferrite discs 517, 515, the magnets 519, 518, 514, 513, and the chassis 501.

According to the first exemplary embodiment of the present disclosure, as shown in FIG. 3, the cover 522 is provided over the chassis 501 to enclose the resonators 502, 503, 504, the connecting conductor 509, and components of the isolation function portion (including but not limited to the center conductor 516, the ferrite discs 517, 515, and the magnets 519, 518, 514, 513). According to some embodiments of the present disclosure, the chassis 501, the resonators 502, 503, 504 and the connecting conductor 509 each can be made of a metal material. According to some other embodiments of the present disclosure, the chassis 501, the resonators 502, 503, 504 and the connecting conductor 509 each can be made of a plastic material with a metalized surface. In addition, the cover 522 can be made of a metal material, or of a plastic material with a metalized surface.

FIG. 4 and FIG. 5 illustrate an alternative embodiment of the isolation-filtering unit according to the first exemplary embodiment of the present disclosure, wherein technical contents of this alternative embodiment which are the same as those of the exemplary first embodiment are omitted to avoid duplicating description, although such technical contents of the first exemplary embodiment can be employed in this alternative embodiment. This alternative embodiment is different from the first embodiment in that, referring to FIG. 4 and FIG. 5, the central conductor 516A of the isolation function portion and the resonators 502A, 503A, 504A of the filtering function portion are integrally formed as one sheetmetal, meanwhile, the connecting conductor 509A is an integral part of the one sheetmetal. That is, in this alternative embodiment, the conductive parts including the central conductor 516A, the connecting conductor 509A and the resonators 502A, 503A, 504A can be processed with one piece of material, compared to that shown in FIG. 2 and FIG. 3 where these corresponding parts are designed with different processes or materials.

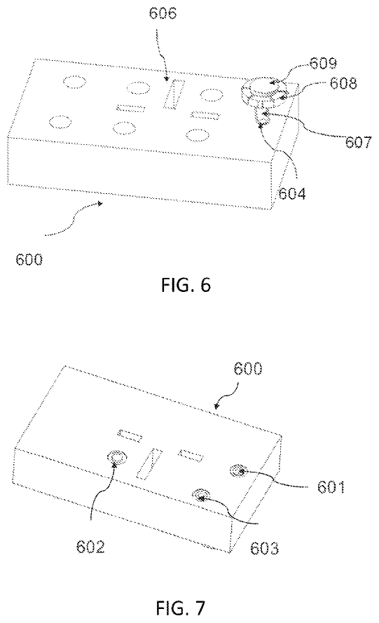

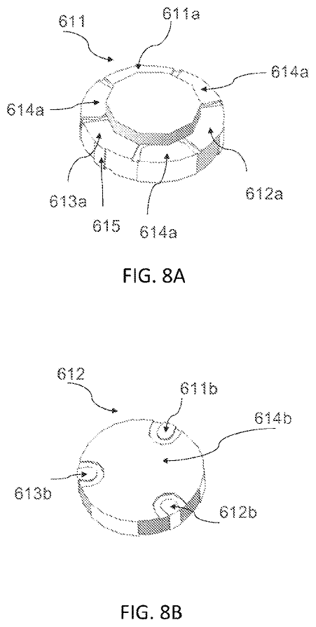

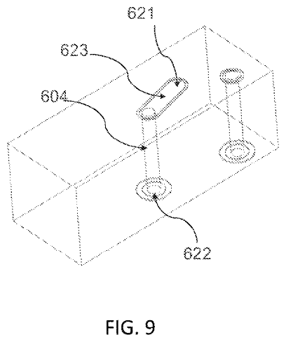

FIG. 6 to FIG. 9 shows an isolation-filtering unit according to a second exemplary embodiment of the present disclosure. In this exemplary embodiment, referring to FIG. 6 to FIG. 9, the isolation-filtering unit 600 comprises a filtering function portion and an isolation function portion integrated with the filtering function portion as a whole. Specifically, the filtering function portion comprises a ceramic body 606, and the isolation function portion comprises a ferrite disc 608 provided on the ceramic body 606 and a magnetic disc 609 provided on the ferrite disc 608. That is, the filtering function portion in this exemplary embodiment operates as a band pass CWG filter, and the isolation function portion in this exemplary embodiment operates as a microstrip circulator/isolator. In this exemplary embodiment, the ceramic body 606 also serves as a carrier for the isolation function portion (including but not limited to the ferrite disc 608 and the magnetic disc 609). Specifically, as shown in FIG. 6 to FIG. 9, the ceramic body 606 is partly metallized to provide the grounding surface and signal ports 601, 602, 603 separated from the grounding surface, while at least some non-metallized surface of the ceramic body 606 provide RF isolation between the grounding surface and the signal ports 601, 602, 603. The ferrite disc 608 is partly metallized to form grounding regions 614a, 614b and conductive traces isolated with the grounding regions 614a, 614b by non-metallized regions of the ferrite disc 608. The conductive traces are separated from each other and extended from an upper surface 611 to a bottom surface 612 of the ferrite disc 608. As shown in FIG. 8A and FIG. 8B, there are three conductive traces, each conductive trace includes a center contradictor 611a, 612a or 613a formed on the upper surface 611 of the ferrite disc 608, a signal pad 611b, 612b or 613b formed on the bottom surface 612 of the ferrite disc 608 and extended from the center contradictor 611a, 612a or 613a, and a transmission line 623 formed on the ceramic body 606 (see FIG. 9). As shown in FIG. 9, the ceramic body 606 includes through holes 604 conductively connected to the conductive traces, so that signal is transmitted from position a at the top surface of the ceramic body 606 to position b (i.e., the signal ports 601, 602, 603) at the bottom surface of the ceramic body 606 through the transmission line 623 and the through holes 604. With this structure, a signal transmission path between the filtering function portion and the isolation function portion is formed. It should be noted that, other parts may be provided between the ferrite disc 608 and the magnetic disc 609, or provided on the top of the magnetic disc 609, in order to optimize the performance of the isolation function portion.

In one example as shown in FIG. 8A, each conductive trace is extended from the upper surface 611 to the bottom surface 612 of the ferrite disc 608 via a side surface 615 of the ferrite disc 608. In another example, each conductive trace is extended from the upper surface 611 to the bottom surface 612 of the ferrite disc 608 via a conductive post (not shown) provided to the side surface of the ferrite disc 608. In yet another example, each conductive trace is extended from the upper surface 611 to the bottom surface 612 of the ferrite disc 608 via a metalized through hole (not shown) formed from the upper surface 611 to the bottom surface 612 of the ferrite disc 608. Moreover, the grounding region of the ferrite disc 608 is connected with the grounding surface of the ceramic body 606 by soldering or other suitably bonding process. With this arrangement, through the conductive traces, transmission lines and through holes on the ceramic body 606, signal is transmitted from the top surface of the ceramic body 606 where the ferrite disc 608 and the magnetic disc 609 are located to the bottom surface of the ceramic body 606 where signal pad is located. Here, the three ports 601, 602, 603 will respectively act as the input port, the output port and the filtering function in-out port of the isolation-filtering unit 600, depending on different application scenarios as mentioned above.

With the isolation-filtering unit provided in the present disclosure, the isolation function portion and the filtering function portion are integrated as a whole and the isolation function portion operates as a circulator or an isolator. The RF performance is improved by a cooperating design of the isolation-filtering unit provided in the present disclosure. The isolation-filtering unit provided in the present disclosure is also optimized to make the isolation function portion provide rejection for filter spurious, or to make the filtering function portion provide rejection for isolator spurious areas. In addition, the IL from circulator/isolator unit's input to filter unit's output is reduced since mismatch between the isolation function portion and the filtering function portion is limited, the trace length between the isolation function portion and the filtering function portion is reduced and the out-of-band attenuation requirement on the isolation-filtering unit is relaxed. With the isolation-filtering unit provided in the present disclosure, the out-of-band attenuation requirement on the isolation-filtering unit is relaxed due to removing extra margin and mismatch. In addition, with the isolation-filtering unit provided in the present disclosure, total BOM (referring to Bill of Materials) cost is reduced since some manufacture processes are saved compared with the circulator/isolator unit and the filter unit in traditional separated design. In addition, weight and size of a Radio including the isolation-filtering unit is reduced since the power amplifier's output power are significant reduced which is benefit from the improved IL of the isolation-filtering unit and smaller size of the isolation-filtering unit. It can achieve good matching between the isolation function portion and the filtering function portion, smaller size and better insertion loss.

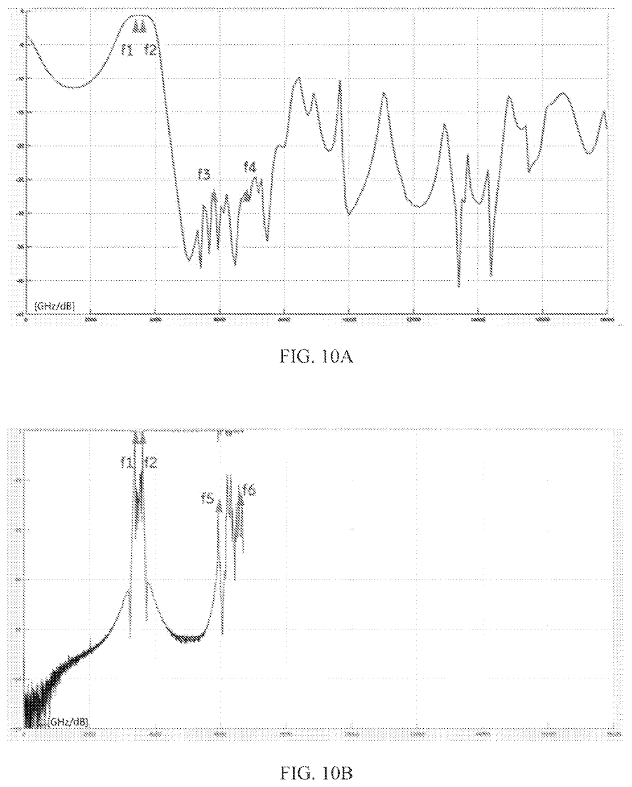

FIG. 10A and FIG. 10B are simulation results showing how the RF performance improved by the isolation-filtering unit provided by the present disclosure, in which the horizontal ordinate indicates Scanning Frequency (GHz) and the longitudinal coordinates indicates Amplitude (dB). FIG. 10A illustrate RF performance of the isolation-filtering unit according to the first exemplary embodiment of the present disclosure, the working frequency is between f1 and f2. FIG. 10B illustrate RF performance of the isolation-filtering unit according to the second exemplary embodiment of the present disclosure, the working frequency is also between f1 and f2, and there has spurious during frequency f5 to f6. With the isolation-filtering unit provided by the present disclosure, it's possible to allow f3-f4 and f5-f6 in same frequency so as to reject the filtering spurious, thereby improving the out band performance of the isolation-filtering unit.

The above-mentioned embodiments merely exemplarily illustrate the principle and structure of the present disclosure, rather than being intended to limit the present disclosure. It should be understood by those skilled in the art that any changes and modifications made to the present disclosure without departing from the general concept of the present disclosure shall fall within the scope of the present disclosure. The scope of the present disclosure shall be defined by the claims of the present disclosure.

1. An isolation-filtering unit configured for performing both an isolation function and a filtering function, the isolation-filtering unit comprising:
an isolation function portion; and
a filtering function portion, wherein the isolation function portion is integrated with the filtering function portion as a whole, and wherein the isolation function portion operates as a circulator or an isolator.

2. The isolation-filtering unit according to claim 1, wherein the isolation function portion is non-conductively coupled to the filtering function portion, or the isolation function portion is conductively connected to the filtering function portion.

3. The isolation-filtering unit according to claim 1, wherein the isolation-filtering unit has at least one isolation function input port and at least one filtering function input-output port.

4. The isolation-filtering unit according to claim 3, wherein the isolation-filtering unit has first, second and third ports,
wherein the first and second ports are configured for transmitting a signal from the first port to the second port and isolating a signal transmitted from the second port to the first port while achieving a filtering function;
wherein the second and third ports are configured for transmitting a signal from the second port to the third port and isolating a signal transmitted from the third port to the second port while achieving a filtering function;
wherein the first and third ports are configured for isolating a signal transmitted from the first port to the third port; and
wherein the third port is selectively configured for being terminated by a load.

5. The isolation-filtering unit according to claim 1, wherein the isolation-filtering unit comprises a chassis for both the isolation function portion and the filtering function portion.

6. The isolation-filtering unit according to claim 5, wherein the filtering function portion comprises the chassis and a plurality of resonators provided within the chassis, the isolation function portion comprises the chassis and a center conductor provided within the chassis, and the resonators are connected to the center conductor by a connecting conductor.

7. The isolation-filtering unit according to claim 6, wherein the connecting conductor is extended from the center conductor of the isolation function portion and is connected to the resonators of the filtering function portion.

8. The isolation-filtering unit according to claim 7, wherein the connecting conductor is connected to the resonators by soldering or by pressing or by rivet connection.

9. The isolation-filtering unit according to claim 6, wherein
the center conductor is inductively coupled to the resonators; or
the center conductor is capacitively coupled to the resonators.

10. The isolation-filtering unit according to claim 6, wherein the central conductor of the isolation function portion and the resonators of the filtering function portion are integrally formed as one sheetmetal; and the connecting conductor is an integral part of the one sheetmetal.

11. The isolation-filtering unit according to claim 6, wherein the chassis, the resonators and the connecting conductor each is made of a metal material, or of a plastic material with a metalized surface.

12. The isolation-filtering unit according to claim 6, further comprising:
a cover provided over the chassis to enclose the resonators, the connecting conductor and the isolation function portion.

13. The isolation-filtering unit according to claim 12, wherein the cover is made of a metal material, or of a plastic material with a metalized surface.

14. The isolation-filtering unit according to claim 1, wherein the filtering function portion comprises a ceramic body, and the isolation function portion comprises a ferrite disc provided on the ceramic body and a magnetic disc provided on the ferrite disc;
wherein the ceramic body also serves as a carrier for the isolation function portion.

15. The isolation-filtering unit according to claim 14, wherein
the ceramic body has through holes therein;
the ferrite disc comprises conductive traces separated from each other and extended from an upper surface to a bottom surface of the ferrite disc; and
the conductive traces are respectively conductively connected to the through holes at the bottom surface of the ferrite disc.

16. The isolation-filtering unit according to claim 15, wherein
each conductive trace is extended from the upper surface to the bottom surface of the ferrite disc via a side surface of the ferrite disc; or
each conductive trace is extended from the upper surface to the bottom surface of the ferrite disc via a conductive post provided to the side surface of the ferrite disc; or
each conductive trace is extended from the upper surface to the bottom surface of the ferrite disc via a metalized through hole formed from the upper surface to the lower surface of the ferrite disc.
